(19) United States
(12) Patent Application Publication
(10) Pub. No.: US 2009/0267094 A1
(43) Pub. Date: Oct. 29, 2009

(54) LIGHT EMITTING DIODE AND METHOD FOR MANUFACTURING THE SAME

(75) Inventors: PAI-SHENG WEI, Tu-Cheng (TW); CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/180,555

(22) Filed: Jul. 27, 2008

(30) Foreign Application Priority Data
Apr. 25, 2008 (CN) 200810066800.8

(51) Int. Cl. H01L 33/00

(52) U.S. Cl. 257/98; 438/27; 257/E33.061

(57) ABSTRACT

The present invention relates to a light emitting diode and a method for manufacturing the same. The light emitting diode includes a base, a light emitting chip on the base, a light permeable encapsulation encapsulating the light emitting chip to the base. The encapsulation defines a plurality of apertures extending from a bottom end toward a top end of the encapsulation.

### BACKGROUND

1. Field of the Invention

The present invention relates to solid state light emitting components, and particularly to a light emitting diode and a method for manufacturing the same.

2. Description of Related Art

Presently, LEDs (light emitting diodes) are preferred for use in non-emissive display devices rather than CCFLs (cold cathode fluorescent material lamp) due to high brightness, long lifespan, and wide color range.

In illumination devices, since the light emitted from the light emitting diode has a weak directive property and cannot reach distances, a traditional light emitting diode always cooperates with a lens for changing an emanative light from the light emitting diode into a substantially parallel light to increase the directive property of the light and its effective distance. However, the lens increases the cost of the illumination device.

What is needed, therefore, is a light emitting diode which has higher directive property and lower cost than the traditional light emitting diode.

### SUMMARY

The present invention provides to a light emitting diode and a method for manufacturing the same. The light emitting diode includes a base, a light emitting chip on the base, a light permeable encapsulation encapsulating the light emitting chip to the base. The encapsulation defines a plurality of apertures extending from a bottom end toward a top end of the encapsulation. The light emitting diode has a light exiting surface at the top end of the encapsulation.

Other advantages and novel features of the present invention will become more apparent from the following detailed description of preferred embodiments when taken in conjunction with the accompanying drawings.

### BRIEF DESCRIPTION OF THE DRAWINGS

FIG. 1 is an isometric view of a light emitting diode according to an exemplary embodiment of the present invention.

FIG. 2 is an isometric, cross-sectional view of the light emitting diode of FIG. 1, taken along line II-II thereof.

FIG. 3 is a front view of FIG. 2.

FIGS. 4 through 7 show steps of a method for manufacturing the light emitting diode of FIG. 1.

FIG. 8 is an explanatory top view of a light emitting diode according to a second exemplary embodiment of the present invention.

FIG. 9 is an explanatory top view of a light emitting diode according to a third exemplary embodiment of the present invention.

### DETAILED DESCRIPTION

Reference will now be made to the drawing figures to describe the exemplary embodiment in detail.

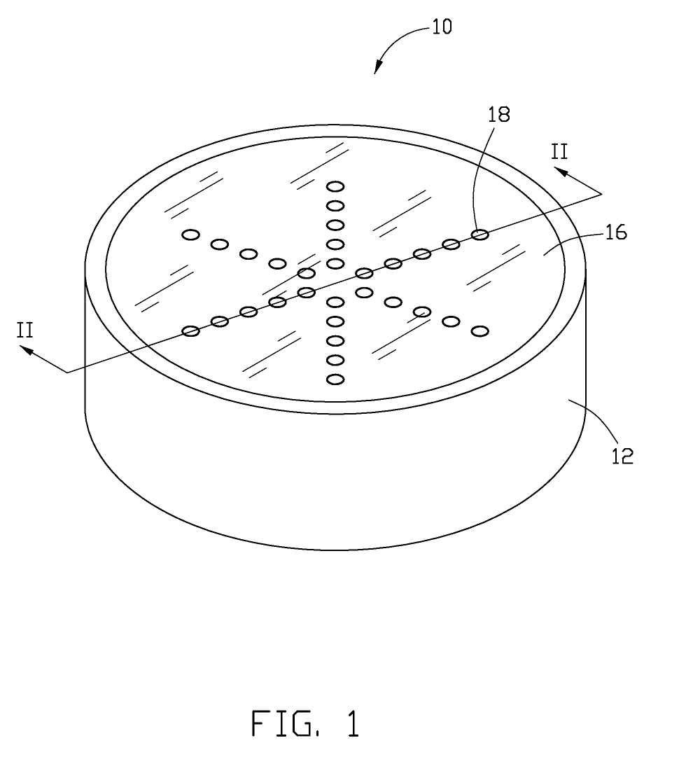

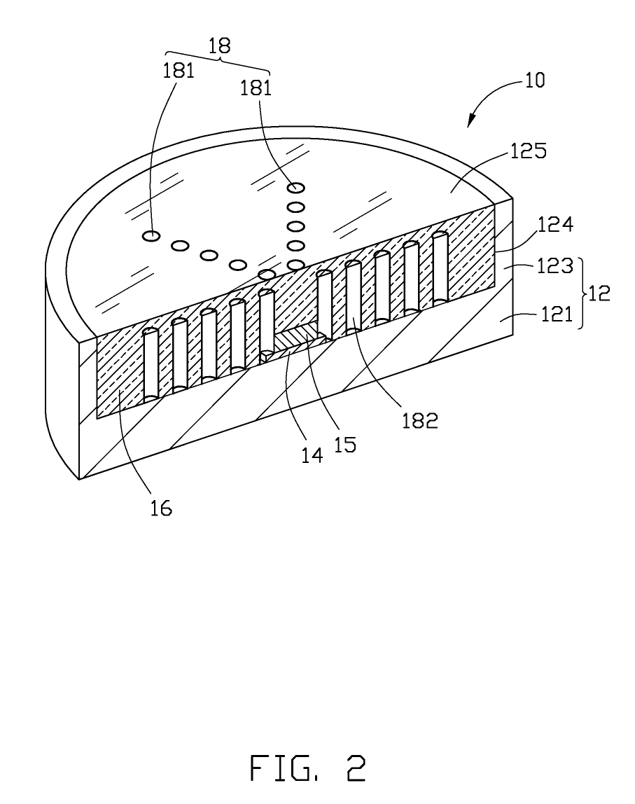

Referring to FIGS. 1 and 2, a light emitting diode 10 (LED) according to an exemplary embodiment of the present invention is shown. The light emitting diode 10 includes a base 12, a light emitting chip 14, an electrode 15, and an encapsulation 16.

The base 12 is of materials having thermal conductivities such as metal or ceramic. In this embodiment, the base 12 is made of metal such as aluminum, or copper. The base 12 includes a round plate-like substrate 121 and a tubular housing 123 extending upwardly from an outer edge of the substrate 121. The substrate 121 electrically connects with an external power supply (not shown). The housing 123 is integrally formed with the substrate 121 from a single piece, and a columned receiving cavity 124 is defined between the housing 123 and the substrate 121. Alternatively, the housing 123 and the substrate 121 may be separately formed and welded or adhered together. A reflective surface (not shown) on an inner side of the housing 123 reflects light impinging on a sidewall of the housing 123 towards a light exiting surface 125 at a top open end of the housing 123. The reflective surface is formed by spattering or coating a reflection layer of aluminum, silver, palladium, or gold, on an inner sidewall of the housing 123. Alternatively, the reflective surface may be formed by smoothing the inner sidewall of the housing 123.

The light emitting chip 14 is received in the receiving cavity 124 defined between the substrate 121 and the housing 123, and adhered to the substrate 121 via silver colloid. The electrode 15 is above the light emitting chip 14 and electrically connects with the substrate 121.

The encapsulation 16 is light permeable material such as epoxy resin, silicone, glass, ultraviolet-cured resin (UV resin), or other material. The encapsulation 16 is filled in the receiving cavity 124 and has a configuration matching the receiving cavity 124. The encapsulation 16 encapsulates the light emitting chip 14 and the electrode 15 in the receiving cavity 124. A top surface of the encapsulation 16 is coplanar with a top surface of the housing 123.

A plurality of column-shaped apertures 182 are defined in the encapsulation 16 via nanoimprint technology. Each of the apertures 182 extends from a bottom end toward a top end of the encapsulation 16. The apertures 182 are arrayed as aperture assembly 18. The aperture assembly 18 includes a plurality of linear aperture arrays 181, each of which radially and outwardly extends from a central axis toward a periphery of the encapsulation 16. The aperture arrays 181 are evenly distributed over the encapsulation 16 along a circumferential orientation. Each of the aperture arrays 181 includes a plurality of equidistantly distributed apertures 182. The innermost apertures 182 of the aperture arrays 181 enclose a circle which surrounds the central axis of the encapsulation 16. The light emitting chip 14 is located just below the circle.

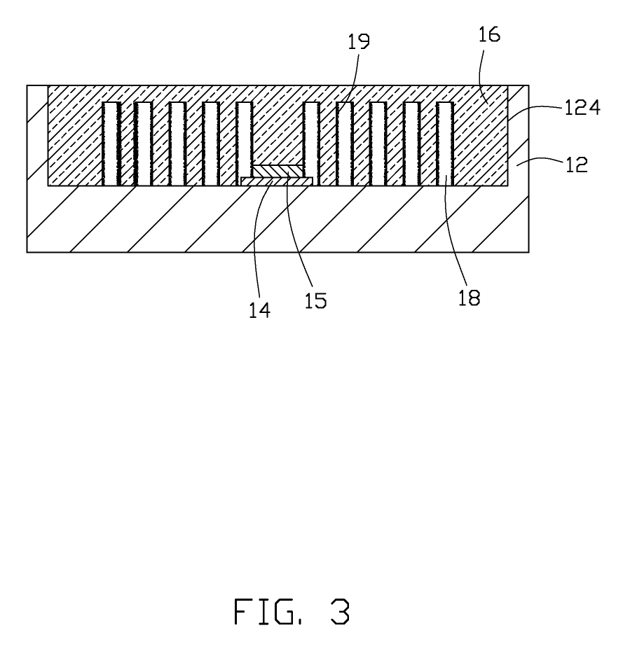

Referring to FIG. 3, a layer of fluorescent material 19 is formed on an inner surface of each of the apertures 182. The fluorescent material 19 is surface treated to maximize adhesion thereof to an inner surface of the aperture 182.

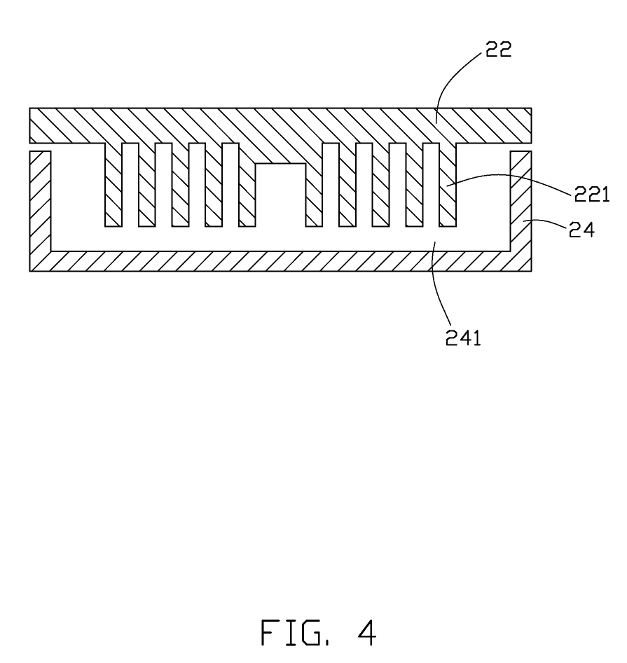

Referring to FIGS. 4 through 7, a method of manufacturing the light emitting diode 10 is as follows:

A first mold 22 is provided, including a plurality of columned projections 221, and a tubular second mold 24 with a columned opening 241 is defined therein. The projection 221 extends downwardly from a bottom face of the first mold 22 and is longer than the aperture 182 of the encapsulation 16. The projections 221 cooperatively form a projection assembly. The configuration of the projection assembly is substantially the same as the configuration of the aperture assembly 18. The configuration of the opening 241 of the second mold 24 is substantially the same as the configuration of the receiving cavity 124 of the base 12.

Referring to FIG. 4, the first mold 22 is placed into the opening 241 of the second mold 24, keeping bottom ends of the projections 221 separated from a bottom end of the opening 241.

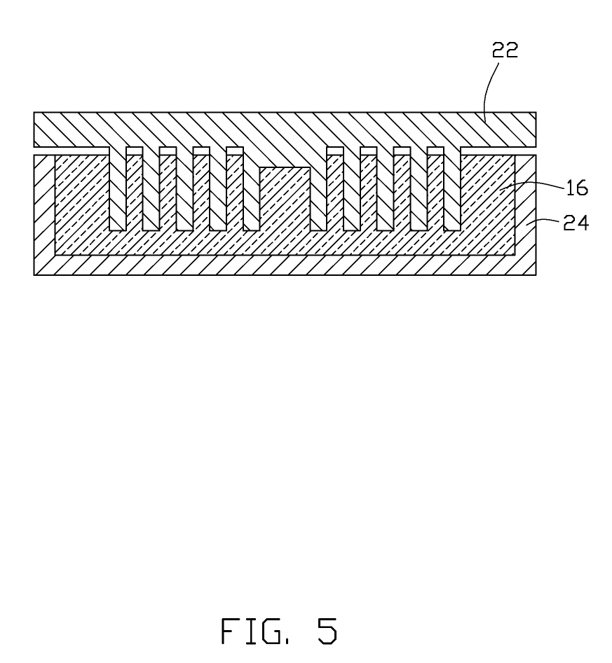

Referring to FIG. 5, molten light penetrating material is filled into the opening 241 of the second mold 24 and cooled.

First mold 22 and second mold 24 are removed, leaving the newly formed encapsulation 16 with aperture assembly 18. Each aperture 182 of the aperture assembly 18 has an open top end and a closed bottom end.

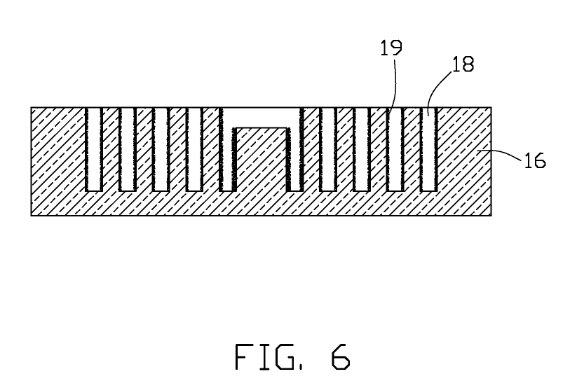

Referring to FIG. 6, surface treated fluorescent material 19 is filled in the apertures 182 of the aperture assembly 18, adhering thereto.

A base 12 with a receiving cavity 124 is provided which has substantially the same configuration as the encapsulation 16 and the light emitting chip 14 and the electrode 15 are fixed in the receiving cavity 124 of the base 12.

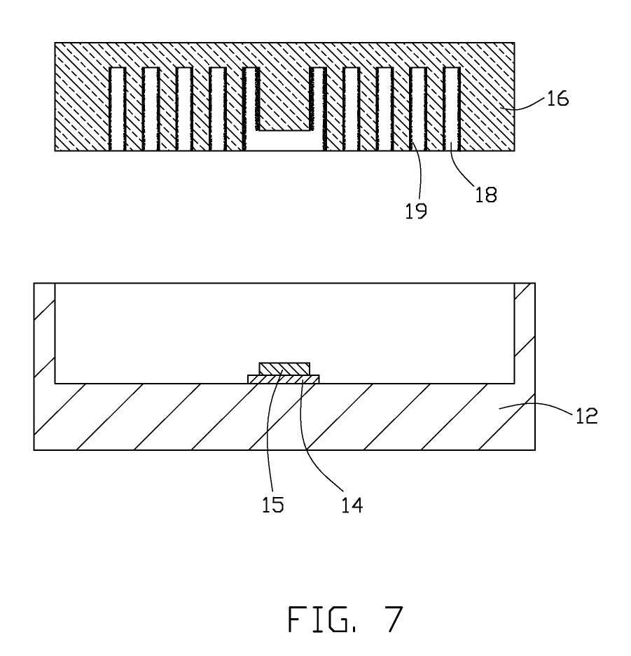

Referring to FIG. 7, the encapsulation 16 is inverted in a top-to-bottom manner so that the open ends of the apertures 182 are inverted to a bottom end of the encapsulation 16, and the encapsulation 16 is secured in the receiving cavity 124 of the base 12 so that the light emitting chip 14 and the electrode 15 are encapsulated in the encapsulation 16 and the light emitting diode 10 is therefore obtained. In this step, the encapsulation 16 is secured to the receiving cavity 124 via interferential engagement between the encapsulation 16 and the receiving cavity 124. Alternatively, the encapsulation 16 may be adhered to the receiving cavity 124 of the base 12.

Referring to FIG. 3, in operation of the light emitting diode 10, one part of the light emitted by the light emitting chip 14 is directly emitted toward the light exiting surface 125 and leaves the encapsulation 16 therefrom. The other part of the light from the light emitting chip 14 is first emitted toward the sidewalls of the apertures 182, and is totally reflected or refracted toward the sidewalls of adjacent apertures 182, and finally leaves the encapsulation 16 from the light exiting surface 125 after being reflected or refracted by the sidewalls of the apertures 182 many times. Another part of the light is emitted toward the sidewall of the housing 123 and is reflected toward the sidewalls of adjacent apertures 182 by the sidewall of the housing 123, and finally leaves the encapsulation 16 from the light exiting surface 125 after being reflected by the sidewall of the housing 123 and reflected or refracted by the sidewalls of the apertures 182 many times.

In this description, one part of the light emitted towards the sidewalls of the apertures 182 is directly and totally reflected by the sidewalls of the apertures 182, while the other part of the light emitted towards the sidewalls of the apertures 182 is refracted by the sidewalls of the apertures 182 and activates the fluorescent material 19 to emit light, which mixes with the light from the light emitting chip 14, producing light of a required color.

In the present light emitting diode 10, since the encapsulation 16 has a different refractive index from the air in the apertures 182, the light is totally reflected or refracted between the sidewalls of the apertures 182 according to Snell's law. The light is therefore reflected or refracted between the sidewalls of the apertures 182 many times and finally leaves the encapsulation 16 from the light exiting surface 125 in different directions. The directive property of the light from the light exiting surface 125 is enhanced, allowing light from the present light emitting diode 10 to reach a far distance.

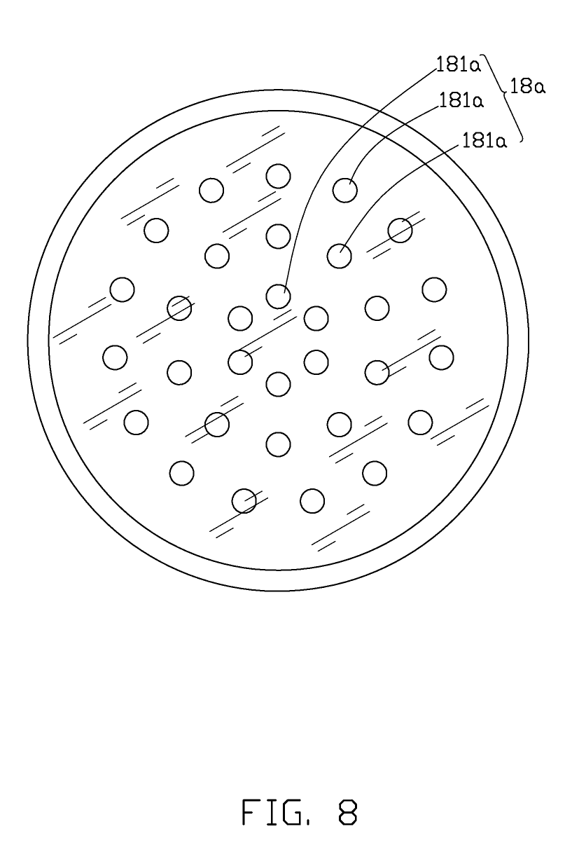

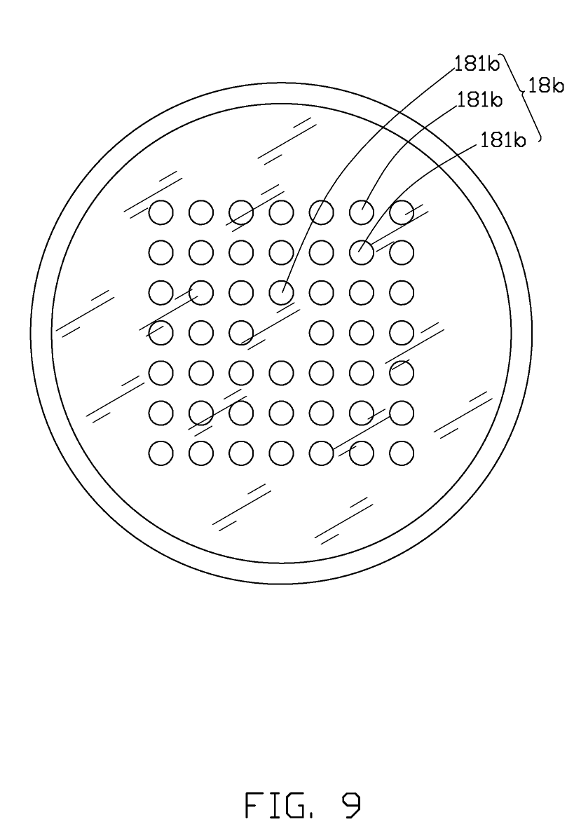

In the present light emitting diode 10, the aperture assembly 18 has a radial configuration, with a plurality of linear aperture arrays 181 radially extending from the central axis toward the periphery of the aperture assembly 18. Alternatively, referring to FIG. 8, the aperture assembly 18a may be round, with a plurality of concentric and evenly spaced round aperture arrays 181a arrayed from the central axis toward the periphery of the aperture assembly 18a. Alternatively, referring to FIG. 9, the aperture assembly 18b may be rectangular, with a plurality of concentric and evenly spaced rectangular aperture arrays 181b arrayed from the central axis toward the periphery of the aperture assembly 18b.

In the present light emitting diode 10, the apertures 182 of the aperture assembly 18 have the same height. Alternatively, the apertures 182 of the aperture assembly 18 may have different heights and gradually increase or decrease from the central axis toward the periphery of the encapsulation 16.

It is to be understood, how ever, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A light emitting diode comprising:
a base;
a light emitting chip on the base; and
a light permeable encapsulation encapsulating the light emitting chip to the base, the encapsulation defining a plurality of apertures extending from a bottom end toward a top end of the encapsulation;
wherein the light emitting diode has a light exiting surface at the top end of the encapsulation.

2. The light emitting diode of claim 1, wherein the apertures are uniformly arrayed to form an aperture assembly, the configuration of the aperture assembly being rectangular or round.

3. The light emitting diode of claim 1, wherein the apertures are uniformly arrayed to form an aperture assembly, the aperture assembly comprising a plurality of linear aperture arrays which radially extend from a central axis toward a periphery of the aperture assembly.

4. The light emitting diode of claim 3, wherein the central axis of the aperture assembly is superposition with the central axis of the encapsulation.

5. The light emitting diode of claim 4, wherein the innermost apertures of the aperture arrays cooperatively enclose a circle surrounding the central axis of the encapsulation.

6. The light emitting diode of claim 5, wherein the circle enclosed by the innermost apertures is just above the light emitting chip.

7. The light emitting diode of claim 3, wherein the apertures are evenly distributed over the encapsulation along a circumferential direction.

8. The light emitting diode of claim 7, wherein the apertures are equidistantly distributed over the encapsulation.

9. The light emitting diode of claim 1, wherein a fluorescent layer is formed on a sidewall of each of the apertures.

10. A method for manufacturing a light emitting diode, comprising:
providing a first mold with a plurality of projections and a second mold with an opening, each projection extending downwardly from a bottom face of the first mold;
placing the projections of the first mold into the opening of the second mold, spacing bottom ends of the projections from the second mold defining the bottom end of the opening;
filling molten light permeable material into the opening of the second mold;
cooling the light penetrate material;
removing the first mold and the second mold, thereby forming an encapsulation having a plurality of apertures, each of which comprises a top open end and a bottom closed end;
providing a base comprising a receiving cavity and securing a light emitting chip therein;
inverting the encapsulation in a top-to-bottom manner so that the open ends of the apertures are inverted below the closed ends of the apertures;
securing the encapsulation to the receiving cavity of the base; and
obtaining the light emitting diode.

11. The method of claim 10, wherein a fluorescent material is filled into the apertures of the encapsulation before the inverted encapsulation is secured to the receiving cavity of the base.

12. The method of claim 11, wherein the fluorescent material is surface treated before being filled into the apertures to enable adherence thereof to sidewalls of the apertures.

13. The method of claim 10, wherein the apertures cooperatively form an aperture assembly which comprises a plurality of linear aperture arrays radially extending from a central axis towards a periphery of the encapsulation.

14. A light emitting diode comprising:
a base having a substrate and a housing extending upwardly from a periphery of the substrate;
a light emitting chip mounted on a center of the substrate;
an encapsulation filled in a space defined between the substrate and the housing, wherein the encapsulation defines a plurality of apertures therein each extending from a bottom end of the encapsulation toward a top end thereof; and
a fluorescent material spread on an inner wall of the encapsulation defining each of the apertures.
